(19) United States
(12) Patent Application Publication
(10) Pub. No.: US 2009/0039954 A1
(43) Pub. Date: Feb. 12, 2009

(54) FAN SYSTEM AND FAN WITH FILTER

(76) Inventors: Cheng-Yi Liu, Taoyuan Hsien (TW); Tsung-Chih Tsai, Taoyuan Hsien (TW)

Correspondence Address: Muncy, Geissler, Olds & Lowe, PLLC, P.O. BOX 1364, FAIRFAX, VA, 22038-1364, US

(21) Appl. No.: 12/186,771

(22) Filed: Aug. 6, 2008

(30) Foreign Application Priority Data
Aug. 10, 2007 (TW) 96129623

(51) Int. Cl. H03H 11/04; H02K 7/14

(52) U.S. Cl. 327/552; 318/3

(57) ABSTRACT

A filter is electrically coupled to a fan or is built-in with a fan, the filter is also electrically coupled a first power terminal and a second power terminal. The filter includes an amplifier, a capacitor, and a divider. The amplifier includes a first terminal, a second terminal and a third terminal, wherein the third terminal is electrically coupled to a power circuit of the fan. The capacitor is electrically coupled between the third terminal of the amplifier and the second power terminal. The divider is electrically coupled between the first power terminal and the second power terminal, wherein a node of the divider is electrically coupled to the second terminal of the amplifier.

### CROSS REFERENCE TO RELATED APPLICATIONS

This Non-provisional application claims priority under 35 U.S.C. §119(a) on Patent Application No(s). 096129623, filed in Taiwan, Republic of China on Aug. 10, 2007, the entire contents of which are hereby incorporated by reference.

### FIELD OF THE INVENTION

The present invention relates to a fan system and a fan with a filter.

### DESCRIPTION OF THE PRIOR ART

As electric products and electronic products continue to develop, heat dissipation thereof becomes an important challenge for product quality and efficiency. Of the heat dissipation devices, fans are popularly used because of low cost and mature development.

However, since fans are operated by magnetic components and further driven by electricity power, electromagnetic interference (EMI) occurs during operation. EMI negatively interferes with other electronic products through electricity loop. Therefore, countries have adopted various EMI standard such as the ETSI (European Telecommunications Standards Institute) EN 300 132-2, established for the design of electronic circuits in fans. The standards request low frequency (25 Hz˜20 KHz) EMI to be under a specific value.

Referring to FIGS. 1 to 3, a conventional fan system includes a filter 10 and a fan 20, wherein a filter 10a/10b/10c is electrically coupled between a power terminal and the fan 20, and especially is electrically connected to the power circuits in the fan 20, for processing of low frequency noise when the power enters the fan 20. FIG. 1 shows that the conventional filter 10a is composed of an inductor L and a capacitor C (L-type filter), FIG. 2 shows that the conventional filter 10b is composed of an inductor L and two capacitors C (π-type filter), and FIG. 3 shows that the conventional filter 10c is composed of two inductors L and a capacitor (T-type filter). For all three conventional filters 10a, 10b and 10c, the low frequency signal generates lower inductive reactance and higher capacitive reactance because of the inductors and capacitors, and causes a certain amount of decrement so that signal noise ratio is raised and noise interference is suppressed.

However, presently, if a fan system must meet low frequency EMI suppression standards, it must choose the inductors with higher inductance and capacitors with higher capacitance. The inductors and capacitors are comparatively large in size, and thus when they are applied to only one single fan, they are configured as an external device. Or when they are applied to a fan tray which has several fans, they occupy a large space.

### SUMMARY OF THE INVENTION

Given the above deficiencies with conventional fan systems, the present invention provides a novel filter design that substantially decreases occupied space in the fan and the fan system.

The present invention discloses a filter which is electrically coupled to a fan or built-in with a fan, and the filter is also electrically coupled to a first power terminal, and a second power terminal. The filter includes an amplifier, a capacitor and a divider. The amplifier includes a first terminal, a second terminal and a third terminal, wherein the third terminal is electrically coupled to a power circuit of the fan. The capacitor is electrically coupled between the third terminal of the amplifier and the second power terminal. The divider is electrically coupled between the first power terminal and the second power terminal, wherein a node of the divider is electrically coupled to the second terminal of the amplifier.

Additionally, the present invention further discloses a fan system having the fan with the filter.

The fan system includes a first power terminal, a second power terminal, a fan and a filter. The filter includes an amplifier, a capacitor and a divider. The amplifier includes a first terminal, a second terminal, and a third terminal, wherein the third terminal is electrically coupled to a power circuit. The capacitor is electrically coupled between the third terminal of the amplifier and the second power terminal. The divider is electrically coupled between the first power terminal and the second power terminal, wherein a node of the divider is electrically coupled to the second terminal of the amplifier.

A detailed description is given in the following embodiments with reference to the accompanying drawings.

### BRIEF DESCRIPTION OF THE DRAWINGS

FIGS. 1 to 3 are schematic diagrams of three conventional filters to a fan.

FIG. 4A is a schematic diagram of a fan system with a filter according to a first embodiment of the present invention.

FIG. 4B is an exploded schematic diagram of FIG. 4A.

FIG. 5 is a schematic diagram of a fan using the filter in FIG. 4A according to a second embodiment of the present invention.

FIG. 6 is a schematic diagram of a fan system with a filter according to a third embodiment of the present invention.

FIG. 7 is a schematic diagram of a fan using the filter in FIG. 6 according to fourth embodiment of the present invention.

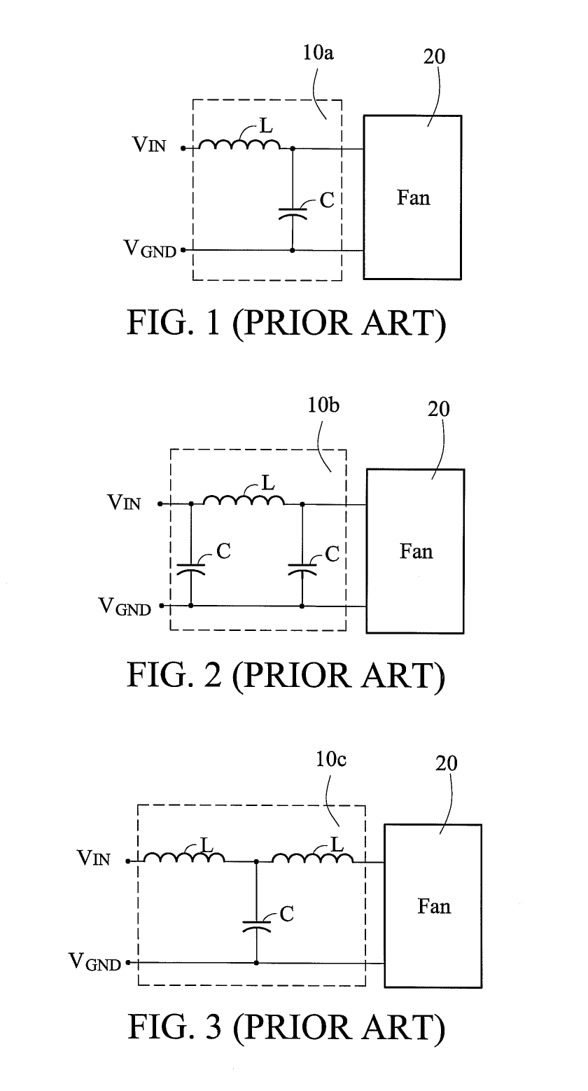

### DETAILED DESCRIPTION

Filters, fans or fan systems with the filters according to the present invention can be better understood with reference to the following drawings.

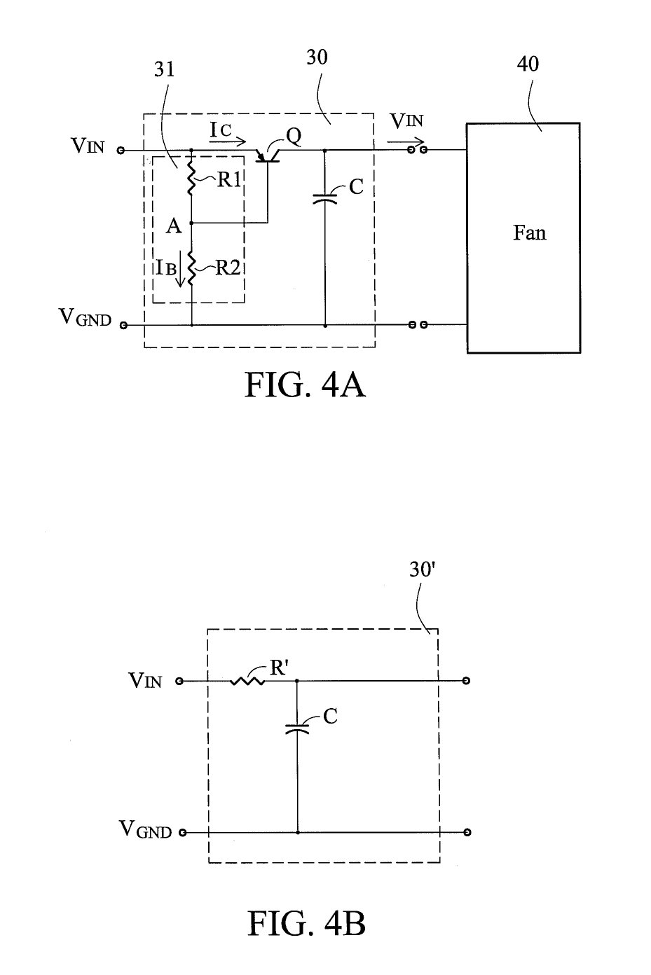

FIG. 4A is a schematic diagram of a fan system with a filter according to a first embodiment of the present invention, wherein the fan system includes a filter 30 and a fan 40. The filter 30 is electrically coupled to a first power terminal V_{IN} and a second terminal V_{GND}, and the fan 40 is electrically coupled to the filter 30.

The fan 40 at least includes a power circuit, a motor and a driving circuit, wherein the power circuit provides the motor and the driving circuit with power supply, and the driving circuit is used to control the motor.

The filter 30 includes an amplifier Q, a capacitor C and a divider 31. The amplifier Q includes a first terminal, a second terminal and a third terminal, wherein the third terminal is electrically coupled to the power circuit of the fan 40. The capacitor C is electrically coupled between the third terminal of the amplifier Q and the second power terminal V_{GND}. The divider 31 is electrically coupled between the first power terminal V_{IN} and the second power terminal V_{GND}, and a node A of the divider is electrically coupled to the second terminal of the amplifier Q.

In this embodiment, the amplifier Q is a transistor, and especially may be implemented as a PNP-type bipolar junction transistor (BJT), wherein a collector of the transistor is electrically coupled to the fan 40, and the divider 31 is electrically coupled to an emitter and a base of the transistor. In addition, in this embodiment, the divider 31 includes a first resistor R1 and a second resistor R2, and the node A between the first resistor R1 and the second resistor R2 is electrically coupled to the base of the transistor.

The voltage of the node A of the filter 30 shown in FIG. 4A as V_{A}=V_{IN}(R2/(R1+R2)), and the current flowing through the second resistor R2 is I_{B}=V_{A}/R2, and βI_{B}<I_{C} (β: current gain). Therefore, the amplifier Q is operated in a amplifying zone and equivalent to a filter 30′ showed in FIG. 4B, wherein a equivalent resistor R′=(R1*R2/(R1+R2))/(1+β). As such, the resistance of the equivalent circuit decreases substantially, and suppression of electromagnetic interference (EMI) can be achieved, thus meeting ETSI EN 300 132-2 standards.

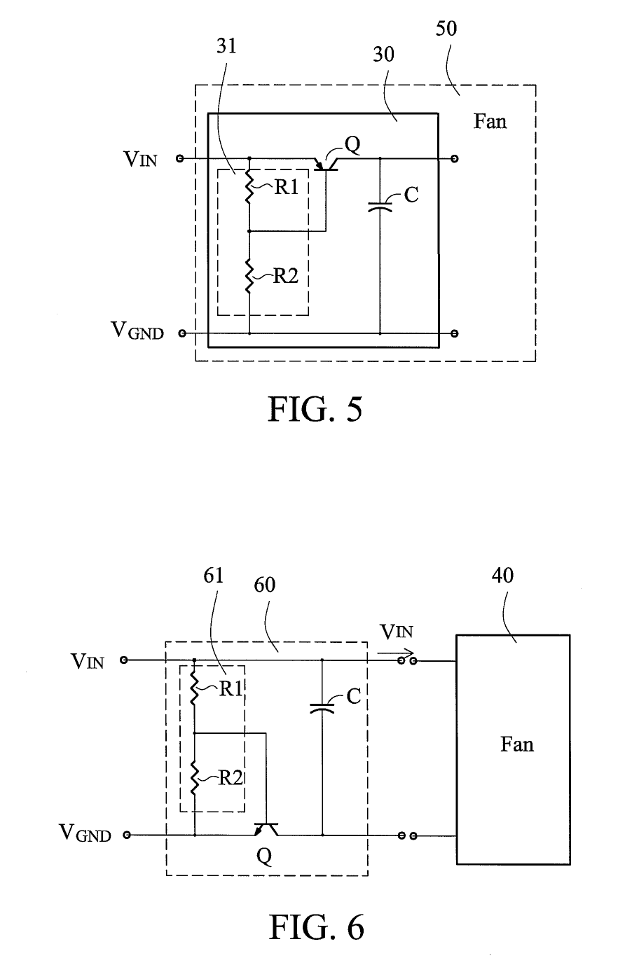

FIG. 5 is a schematic diagram of a fan using the filter in FIG. 4A according to a second embodiment of the present invention. The filter 30 described above is integrated in a fan 50, receives power supply and processes EMI. Since the filter has been described above, repeated description will not be discussed hereafter for brevity.

FIG. 6 is a schematic diagram of a fan system with a filter according to a third embodiment of the present invention. The fan system includes a filter 60, and a fan 40, wherein the filter 60 is electrically coupled to a first power terminal V_{GND} and a second power terminal V_{IN}, and the fan 40 is electrically coupled to the filter 60.

The filter 60 includes an amplifier Q, a capacitor C and a divider 61. The amplifier Q includes a first terminal, a second terminal and a third terminal, wherein the third terminal is electrically coupled to the power circuit of the fan 40. The capacitor C is electrically coupled between the third terminal of the amplifier Q and the second power terminal V_{IN}. The divider 61 is electrically coupled between the first power terminal V_{IN} and the second power terminal V_{GND}, and it has a node A electrically coupled to the second terminal of the amplifier Q.

In this embodiment, the amplifier Q is a transistor, and especially may be implemented as an NPN-type BJT, and a collector of the transistor is electrically coupled to the fan 40, and the divider 61 is electrically coupled to an emitter and a base of the transistor. The divider 61 includes a first resistor R1 and a second resistor R2, and the node A between the first resistor R1 and the second resistor R2 is electrically coupled to the base of the transistor.

The divider 61 of the filter 60 shown in FIG. 6 is equivalent to an equivalent resistor R′=(R1*R2/(R1+R2))/(1+β). As such, the resistance of the equivalent circuit decreases substantially, and suppression of electromagnetic interference (EMI) can be achieved, thus meeting ETSI EN 300 132-2 standard.

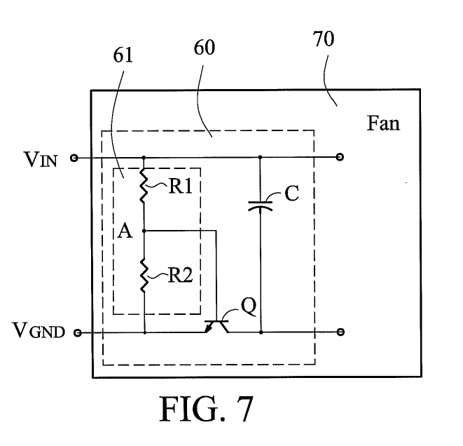

FIG. 7 is a schematic diagram of a fan using the filter in FIG. 6 according to a fourth embodiment of the present invention. The filter 60 described above is integrated in a fan 70 and receives power supply and processes EMI. Since the filter has been described above, repeated description will not be discussed hereafter for brevity.

In conclusion, noise from EMI is suppressed due to the filter of the present invention reducing the value of the resistor by means of the character of the amplifier. Moreover, because of the amplification of the amplifier, the sizes of the resistors and capacitors are not as large as those in the prior art, therefore, occupied space is reduced and costs are lowered.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A filter, electrically coupled to a fan, a first power terminal and a second power terminal, the filter comprising:
an amplifier, comprising a first terminal, a second terminal and a third terminal, wherein the first terminal is electrically coupled to the first power terminal, and the third terminal is electrically coupled to a power circuit of the fan;
a capacitor, electrically coupled between the third terminal of the amplifier and the second power terminal; and
a divider, electrically coupled between the first power terminal and the second power terminal, wherein a node of the divider is electrically coupled to the second terminal of the amplifier.

2. The filter as claimed in claim 1, wherein the fan further comprises a motor and a driving circuit, and the power circuit provides power to the motor and the driving circuit.

3. The filter as claimed in claim 1, wherein the filter and the fan are separated, the first terminal of the amplifier is electrically coupled to the first power terminal.

4. The filter as claimed in claim 1, wherein the filter is built-in with the fan, and the fan is electrically coupled between the first power terminal and the second power terminal.

5. The filter as claimed in claim 1, wherein the amplifier is a PNP-type bipolar junction transistor (BJT) or an NPN-type BJT, and the first terminal of the amplifier is a emitter, the second terminal of the amplifier is a base and the third terminal of the amplifier is a collector.

6. The filter as claimed in claim 5, wherein when the amplifier is a PNP-type BJT, and the second power terminal is a ground terminal, or when the amplifier is an NPN-type BJT, and the first power terminal is a ground terminal.

7. The filter as claimed in claim 1, wherein the divider comprises a first resistor and a second resistor, wherein the node between the first resistor and the second resistor is electrically coupled to the second terminal of the amplifier.

8. A fan, comprising a filter and a power circuit with a first power terminal and a second power terminal, wherein the filter comprising:
an amplifier, comprising a first terminal, a second terminal and a third terminal, wherein the third terminal is electrically coupled to the power circuit;
a capacitor, electrically coupled between the third terminal of the amplifier and the second power terminal; and
a divider, electrically coupled between the first power terminal and the second power terminal, wherein a node of the divider is electrically coupled to the second terminal of the amplifier.

9. The filter as claimed in claim 8, wherein the fan further comprises a motor and a driving circuit, and the power circuit provides power to the motor and the driving circuit.

10. The filter as claimed in claim 8, wherein if the filter and the fan are separated, the first terminal of the amplifier is electrically coupled to the first power terminal; or if the filter is built-in with the fan, and the fan is electrically coupled between the first power terminal and the second power terminal.

11. The filter as claimed in claim 8, wherein the amplifier is a PNP-type bipolar junction transistor (BJT) or an NPN-type BJT, and the first terminal of the amplifier is a emitter, the second terminal of the amplifier is a base and the third terminal of the amplifier is a collector.

12. The filter as claimed in claim 11, wherein when the amplifier is a PNP-type BJT, and the second power terminal is a ground terminal; or when the amplifier is an NPN-type BJT, and the first power terminal is a ground terminal.

13. The filter as claimed in claim 8, wherein the divider comprises a first resistor and a second resistor, and the node between the first resistor and the second resistor is electrically coupled to the second terminal of the amplifier.

14. A fan system, comprising:
a power circuit comprising a first power terminal, and a second power terminal;
a fan; and
a filter, comprising:
an amplifier, comprising a first terminal, a second terminal and a third terminal, wherein the third terminal is electrically coupled to the power circuit;
a capacitor, electrically coupled between the third terminal of the amplifier and the second power terminal; and
a divider, electrically coupled between the first power terminal and the second power terminal, wherein a node of the divider is electrically coupled to the second terminal of the amplifier.

15. The fan system as claimed in claim 14, wherein the fan further comprises a motor and a driving circuit, and the power circuit provides power to the motor and the driving circuit.

16. The fan system as claimed in claim 14, wherein if the filter and the fan are separated, the first terminal of the amplifier is electrically coupled to the first power terminal; or if the filter is built-in with the fan, and the fan is electrically coupled between the first power terminal and the second power terminal.

17. The fan system as claimed in claim 14, wherein the amplifier is a PNP-type bipolar junction transistor (BJT) or an NPN-type BJT, and the first terminal of the amplifier is a emitter, the second terminal of the amplifier is a base and the third terminal of the amplifier is a collector.

18. The fan system as claimed in claim 17, wherein when the amplifier is a PNP-type BJT, the second power terminal is a ground terminal, or when the amplifier is an NPN-type BJT, the first power terminal is a ground terminal.

19. The fan system as claimed in claim 14, wherein the divider comprises a first resistor and a second resistor, and the node between the first resistor and the second resistor is electrically coupled to the second terminal of the amplifier.
